(19) United States
(12) Patent Application Publication
(10) Pub. No.: US 2026/0313212 A1
(43) Pub. Date: Oct. 8, 2026

(54) CAMERA PASS-THROUGH

(71) Applicant: Bio-Rad Laboratories, Inc., Hercules, CA (US)

(72) Inventors: Jeffry Ceremony, Hercules, CA (US); Timothy Andrews, Hercules, CA (US)

(21) Appl. No.: 19/574,840

(22) Filed: Mar. 23, 2026

Related U.S. Application Data
(60) Provisional application No. 63/782,514, filed on Apr. 2, 2025.

(51) Int. Cl. H04N 23/54; H04N 23/52; H05K 1/02

(52) U.S. Cl. CPC H04N 23/54; H04N 23/52; H05K 1/0206; H05K 2201/10151

(57) ABSTRACT

A camera pass-through is disclosed herein. One aspect relates to a camera for capturing images. The camera includes a camera chip, a multilayer printed circuit board (“PCB”) communicatively coupled with the camera chip, the PCB having a top layer, a bottom layer, and at least one internal layer, the traces for powering the camera chip and traces for receiving data from the camera chip extend through the at least one internal layer of the PCB, and a chamber cover sealingly coupled to the PCB around the camera chip to define a hermetically sealed volume containing the camera chip.

### CROSS REFERENCES TO RELATED APPLICATIONS

The present application claims priority to U.S. Provisional Patent Application Nos. 63/782,514 filed Apr. 2, 2025; the full disclosures of which are incorporated herein by reference in their entirety for all purposes.

### BACKGROUND

Improved imaging techniques have led to advances in imaging such as is used in Western blot. The use of cameras in western blotting has revolutionized the way researchers detect and analyze protein signals, offering increased sensitivity, precision, and convenience compared to traditional methods like X-ray film. Digital imaging systems equipped with high-resolution cameras are widely used to capture the luminescent, chemiluminescent, or fluorescent signals emitted from a sample. These cameras, often coupled with imaging software, allow researchers to visualize and quantify results of analysis. This eliminates the time-consuming process of developing and scanning film while providing a more accurate and dynamic range for detecting faint or strong signals.

Although imaging techniques have improved over time, further improvements and advancements are desired.

### BRIEF SUMMARY

A camera pass-through is disclosed herein. One aspect relates to a camera for capturing images. The camera includes a camera chip, a multilayer printed circuit board (“PCB”) communicatively coupled with the camera chip, the PCB having a top layer, a bottom layer, and at least one internal layer, the traces for powering the camera chip and traces for receiving data from the camera chip extend through the at least one internal layer of the PCB, and a chamber cover sealingly coupled to the PCB around the camera chip to define a hermetically sealed volume containing the camera chip.

In some embodiments, no wire extends through the chamber cover. In some embodiments, the chamber cover has a top cover sealingly coupled to a top surface of the PCB and a bottom cover sealingly coupled to a bottom surface of the PCB. In some embodiments, the top cover is sealingly coupled to the top surface of the PCB by a first gasket located on the top surface of the PCB and extending around the camera chip. In some embodiments, the bottom cover is sealingly coupled to the bottom surface of the PCB by a second gasket located on the bottom surface of the PCB and extending around the camera chip. In some embodiments, the top cover can include a transparent window by which the camera chip can capture images of an item outside of the sealed volume. In some embodiments, the transparent window can be a sapphire window. In some embodiments, the bottom cover can be a heat sink.

In some embodiments, the camera includes a thermo-electric cooler (“TEC”) located inside of the sealed volume and thermally coupled by a conductive pathway to the camera chip and to the heat sink. In some embodiments, the PCB can have TEC traces extending through at least one internal layer of the PCB. In some embodiments, the TEC traces power the TEC and control the TEC.

In some embodiments, the camera can include a thermal conductor positioned between the TEC and the camera chip. The thermal conductor can form a portion of the conductive pathway between the TEC and the camera chip. In some embodiments, the camera chip can be mounted at a location on the PCB. In some embodiments, the thermal conductive pathway can include a region of the PCB. In some embodiments, the thermal conductive pathway is at the location at which the camera chip is mounted on the PCB and extends through the PCB. In some embodiments, the thermal conductive pathway can include a plurality of vias extending through at least a portion of the PCB. In some embodiments, the plurality of vias are arranged in a grid pattern. In some embodiments, the plurality of vias are arranged in an offset grid pattern. In some embodiments, each of the vias is copper plated or copper filled.

In some embodiments, the top layer of the PCB is at least partially covered by a first homogenous copper plate. In some embodiments, the bottom layer of the PCB is at least partially covered by a second homogenous copper plate. In some embodiments, the first copper plate is covered by a first masking. In some embodiments, the second copper plate is covered by a second masking. In some embodiments, the traces extend through the at least one internal layer from a location inside of the hermetically sealed volume to a location outside of the hermetically sealed volume.

One aspect relates to an imager. The imager includes a sample receiving area that can receive a biological sample for imaging, and a camera. The camera can include a camera chip, a multilayer printed circuit board (“PCB”) having a top layer, a bottom layer, at least one internal layer, and traces extending through the at least one internal layer of the PCB, the traces including at least one camera trace for powering the camera chip, and a chamber cover sealingly coupled to the PCB around the camera chip to define a hermetically sealed volume containing the camera chip.

In some embodiments, no wire extends through the chamber cover. In some embodiments, the chamber cover includes a top cover sealingly coupled to a top surface of the PCB and a bottom cover sealingly coupled to a bottom surface of the PCB. In some embodiments, the top cover is sealingly coupled to the top surface of the PCB by a first gasket located on the top surface of the PCB and extending around the camera chip. In some embodiments, the bottom cover is sealingly coupled to the bottom surface of the PCB by a second gasket located on the bottom surface of the PCB and extending around the camera chip. In some embodiments, the top cover comprises a transparent window by which the camera chip can capture images of an item outside of the sealed volume. In some embodiments, the transparent window can be a sapphire window.

In some embodiments, the bottom cover can be a heat sink. In some embodiments, the imager further includes a thermo-electric cooler (“TEC”) located inside of the sealed volume and thermally coupled by a conductive pathway to the camera chip and to the heat sink. In some embodiments, the PCB includes TEC traces extending through at least one internal layer of the PCB, which TEC traces power the TEC and control the TEC.

In some embodiments, the imager further includes a thermal conductor positioned between the TEC and the camera chip and that forms a portion of the conductive pathway between the TEC and the camera chip. In some embodiments, the camera chip is mounted at a location on the PCB. In some embodiments, the thermal conductive pathway includes a region of the PCB. In some embodiments, the thermal conductive pathway is at the location at which the camera chip is mounted on the PCB and extends through the PCB. In some embodiments, the thermal conductive pathway includes a plurality of vias extending through at least a portion of the PCB. In some embodiments, the plurality of vias are arranged in a grid pattern. In some embodiments, the plurality of vias are arranged in an offset grid pattern. In some embodiments, each of the vias is copper plated or copper filled.

In some embodiments, the top layer of the PCB is at least partially covered by a first homogenous copper plate. In some embodiments, the bottom layer of the PCB is at least partially covered by a second homogenous copper plate. In some embodiments, the first copper plate is covered by a first masking. In some embodiments, the second copper plate is covered by a second masking. In some embodiments, the traces extend through the at least one internal layer from a location inside of the hermetically sealed volume to a location outside of the hermetically sealed volume.

One aspect relates to a method of imaging a biological sample. The method includes receiving a sample within a sample receiving area of an imager, and capturing an image of the sample with a camera. The camera can include a camera chip, a multilayer printed circuit board (“PCB”) having a top layer, a bottom layer, at least one internal layer, and traces extending through the at least one internal layer of the PCB, the traces including at least one camera trace for powering the camera chip, and a chamber cover sealingly coupled to the PCB around the camera chip to define a hermetically sealed volume containing the camera chip.

In some embodiments, no wire extends through the chamber cover. In some embodiments, the chamber cover includes a top cover sealingly coupled to a top surface of the PCB and a bottom cover sealingly coupled to a bottom surface of the PCB. In some embodiments, the top cover is sealingly coupled to the top surface of the PCB by a first gasket located on the top surface of the PCB and extending around the camera chip. In some embodiments, the bottom cover is sealingly coupled to the bottom surface of the PCB by a second gasket located on the bottom surface of the PCB and extending around the camera chip. In some embodiments, the top cover includes a transparent window by which the camera chip can capture images of an item outside of the sealed volume. In some embodiments, the transparent window can be a sapphire window. In some embodiments, the bottom cover can be a heat sink.

In some embodiments, the camera further includes a thermo-electric cooler (“TEC”) located inside of the sealed volume and thermally coupled by a conductive pathway to the camera chip and to the heat sink. In some embodiments, the PCB can include TEC traces extending through at least one internal layer of the PCB. In some embodiments, the TEC traces power the TEC and control the TEC.

In some embodiments, the camera further includes a thermal conductor positioned between the TEC and the camera chip which thermal conductor can form a portion of the conductive pathway between the TEC and the camera chip. In some embodiments, the camera chip is mounted at a location on the PCB. In some embodiments, the thermal conductive pathway can include a region of the PCB. In some embodiments, the thermal conductive pathway is at the location at which the camera chip is mounted on the PCB and extends through the PCB. In some embodiments, the thermal conductive pathway can include a plurality of vias extending through at least a portion of the PCB. In some embodiments, the plurality of vias are arranged in a grid pattern. In some embodiments, the plurality of vias are arranged in an offset grid pattern. In some embodiments, each of the vias is copper plated or copper filled.

In some embodiments, the top layer of the PCB is at least partially covered by a first homogenous copper plate. In some embodiments, the bottom layer of the PCB is at least partially covered by a second homogenous copper plate. In some embodiments, the first copper plate is covered by a first masking. In some embodiments, the second copper plate is covered by a second masking. In some embodiments, the traces extend through the at least one internal layer from a location inside of the hermetically sealed volume to a location outside of the hermetically sealed volume.

### BRIEF DESCRIPTION OF THE DRAWINGS

FIG. 1 is a perspective view of one embodiment of an imager.

FIG. 2 is a schematic depiction of one embodiment of the imager.

FIG. 3 is a perspective view of one embodiment of the camera assembly.

FIG. 4 is an exploded view of one embodiment of the camera assembly.

FIG. 5 is a schematic depiction of an embodiment of a portion of the camera assembly including a conductive pathway.

FIG. 6 is a schematic depiction of an embodiment of a portion of the camera assembly including a plurality of vias.

FIG. 7 is a depiction of a plurality of vias arranged in (a) a regular grid pattern, and (b) an offset grid pattern.

### DETAILED DESCRIPTION

Digital imaging has provided significant benefits to imaging, such as imaging performed as part of western blot. However, the use of digital imaging and the thereto necessary digital imagers has created some problems. For example, certain high resolution imagers perform best in a very controlled environment. This can include actively cooling all or portions of the camera image sensor chip and/or controlling the atmosphere in which the camera image sensor chip is located. In some applications, a camera image sensor chip can be actively cooled, and can be contained within a sealed chamber. This chamber can be a vacuum chamber, or can be filled with a desired gas, such as an inert gas. The sealing of the chamber is complicated by the fact that the components within the chamber must be powered, controlled, and/or output data. The powering, control, and/or outputting of data is achieved by electrical and/or communicating connection to the components within the chamber. Traditionally, this has been achieved by one or several wires that pass from inside of the chamber to outside of the chamber. These wires are sealed by potting. This potting can have inadequacies including, in some instances, not effectively sealing over the lifespan of the imager. Also, potting and adhesive sealing techniques can be labor intensive therefore undesirable. The proposed pass through invention makes use of the internal layers of the printed circuit board to conduct power and electrical signals within the inner layers of the printed circuit board outside the chamber. Thus, eliminating the need to route wires or cables inside and outside of the gas tight chamber.

The present relates to systems, methods, and/or devices for improving imagers. This includes the creation of a camera pass through by which a Camera Image Sensor Chip inside of a sealed chamber can be electrically and/or communicatingly coupled to components outside of the sealed chamber. This camera pass through can comprise one or more traces extending through at least one internal layer of a printed circuit board (“PCB”) to which a Camera Image Sensor Chip is attached.

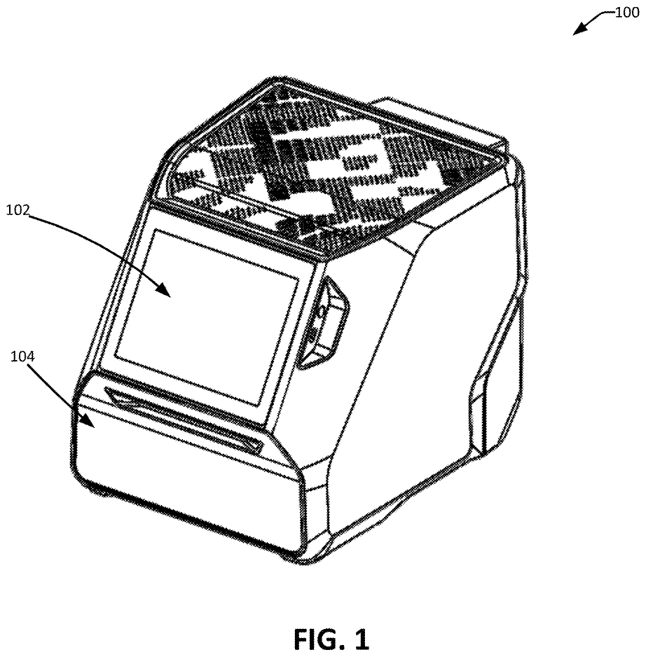

With reference now to FIG. 1, a perspective view of one embodiment of an imager 100 is depicted. The imager 100 can be configured for imaging one or more samples including, for example, western blot, or the like. The imager 100 can include a display 102 and a sample receiving area 104. The display 102 can comprise a screen and can be configured to display information and/or images to the user, to provide one or more outputs to the user, and/or to receive one or more inputs from the user. The sample receiving area 104 can be configured to receive and/or hold a sample, including for example, a membrane used in connection with western blot. The sample in the receiving area 104 can be imaged by the imager 100.

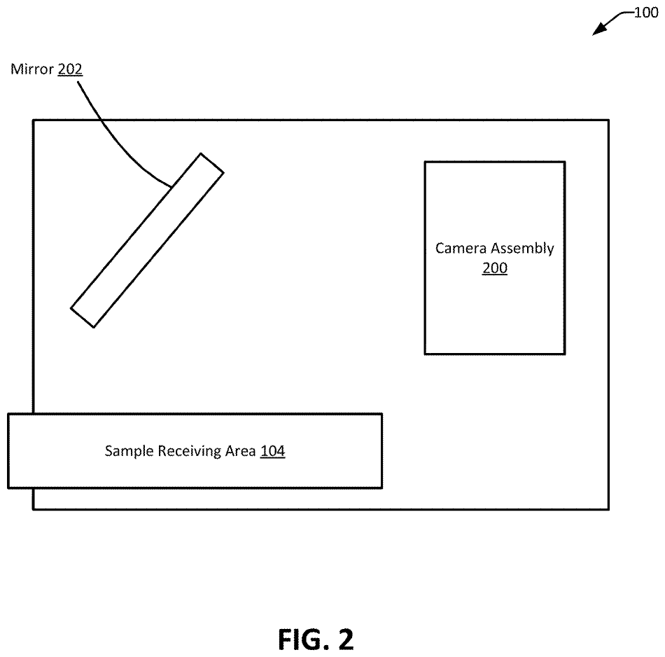

With reference now to FIG. 2, a schematic depiction of one embodiment of the imager 100 is shown. As seen in FIG. 2, the imager 100 can include a camera assembly 200. The camera assembly 200 can be configured to image the sample in the sample receiving area 104. As indicated in FIG. 2, in some embodiments, the imager 100 can include a mirror 202 which can be positioned above the sample receiving area 104 by which mirror 202 the camera assembly 200 can image the sample.

In some embodiments, a sample can be placed in the sample receiving area 104 and/or can be received in the sample receiving area 104. The sample can then be imaged by the camera assembly 200. In some embodiments, this can include controlling the camera assembly 200 to illuminate all or portions of the sample and/or to capture an image of the sample.

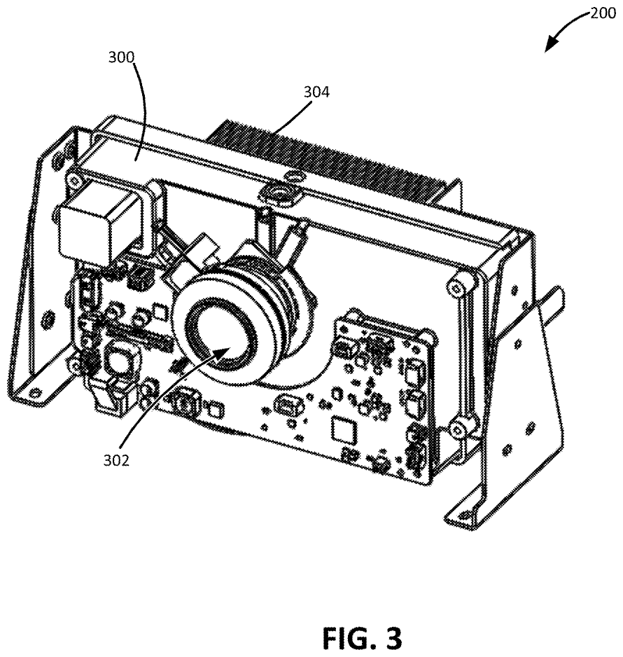

With reference now to FIG. 3, a perspective view of one embodiment of the camera assembly 200 is shown. The camera assembly 200 includes a filter wheel/lens assembly 300 can comprise a lens 302 by which the sample can be imaged. The filter wheel/lens assembly 300 can further include a filter wheel. The filter wheel, not shown, can comprise a plurality of filters, each of which can filter one or more light wavelengths to allow imaging of one or more targeted wavelengths. In some embodiments, the filter wheel can be manipulated by one or more motors such that a desired one or more filters can be positioned in the optical stack between the lens 302 and the camera.

The camera assembly 200 can further include a heat sink 304. The heat sink 304 can be configured to sink heat from one or more components in the camera assembly 200. The heat sink 304 can comprise a thermally conductive material such as a metal including, for example, aluminum, and can, in some embodiments, comprise one or more features configured to dissipate heat such as one or more fins.

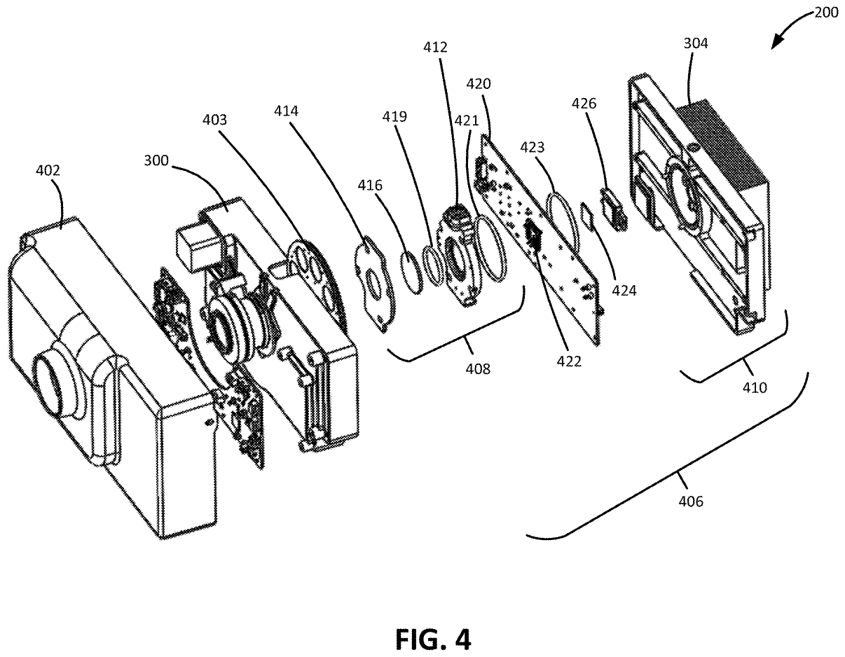

With reference now to FIG. 4, an exploded view of one embodiment of the camera assembly 200 is shown. This includes, although not shown in FIG. 3, a camera cover 402 configured to provide an external housing to components of the camera assembly 200, and a fan shroud configured to at least partially enclose a fan. In some embodiments, the fan shroud can direct airflow over the heat sink 304 to thereby enhance cooling provided by the heat sink 304.

As previously discussed, the camera assembly 200 includes the filter wheel/lens assembly 300, which can be contained inside of the camera cover 402. As discussed above, the filter wheel/lens assembly 300 can include one or several lenses and/or a filter wheel 403 comprising a plurality of filters.

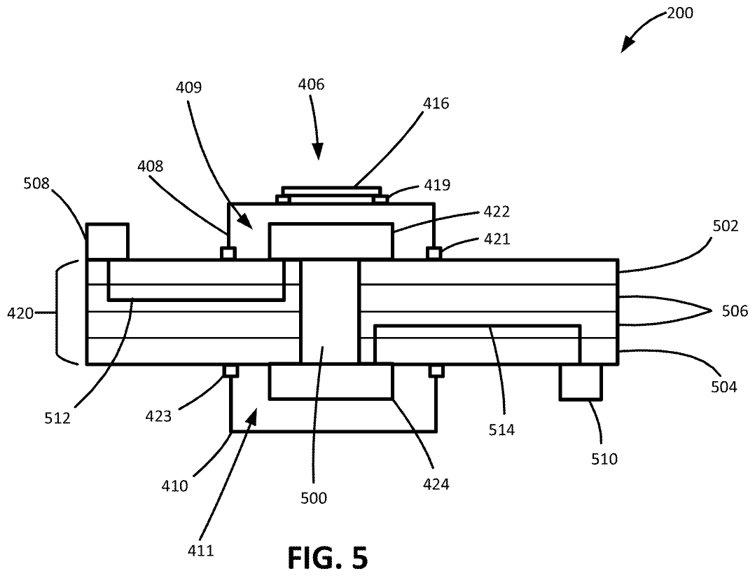

The camera assembly 200 includes the chamber cover assembly 406. The chamber cover assembly 406 can include a front chamber cover assembly 408, also referred to herein as a top cover 408, and a rear chamber cover assembly 410, also referred to herein as a bottom cover 410. The front chamber cover assembly 408 can mate with a front, also referred to as a top surface of a camera printed circuit board (“PCB”) 420 to, as shown in FIG. 5, define a front chamber 409, also referred to herein as an upper chamber 409 and the rear chamber cover assembly 410 can mate with a back, also referred to as a bottom surface of the camera PCB 420 to, as shown in FIG. 5, form a rear chamber 411, also referred to herein as the lower chamber 411. Specifically, in some embodiments, the top cover 408 can sealingly mate and/or couple to a top surface of the camera PCB 420 and the bottom cover 410 can sealingly mate and/or couple to a bottom surface of the camera PCB 420. In some embodiments, the combination of the front chamber cover assembly 408 and the rear chamber cover assembly 410 can encapsulate the camera chip 422 to thereby seal the camera chip 422 within the chamber cover assembly 406. Thus, in some embodiments, the chamber cover assembly 406 can sealing couple to the camera PCB 420 around the camera chip 422 to define a sealed volume containing the camera chip 422, which sealed volume can be a hermetically sealed volume.

The front chamber cover assembly 408 can be configured to enclose the camera chip 422 and to provide a window by which the camera chip 422 can image, and specifically can image a sample in the sample receiving area 104 of the imager 100. The front chamber cover assembly 408 can include a chamber cover 412, a window retainer 414, a window 416, which can comprise a transparent window and more specifically can comprise a sapphire window, and one or more O-rings 419, 421, 423, also referred to herein as one or more gaskets. In some embodiments, a first O-ring 421, also referred to as a front O-ring 421 can be positioned between the camera PCB 420 and the chamber cover 414. A second O-ring 423, also referred to herein as a rear O-ring 323 can be positioned between the camera PCB 420 and the heat sink 304. A window O-ring 419 can be positioned between the chamber cover 412 and the window 416, which window 416 can be held in place on the chamber cover 412 compressed against the second O-ring 419 by the window retainer 414. In some embodiments, the top cover 408 can sealing couple to the top surface of the camera PCB 420 by a first gasket 421 located on the top surface of the camera PCB 420 and extending around the camera chip 422, and the bottom cover 410 can sealingly couple to the bottom surface of the camera PCB 420 by a second gasket located on the bottom surface of the camera PCB 420 and extending around the camera chip 422.

In some embodiments, and as shown in FIG. 4, the rear chamber cover assembly 410 can be formed into the heat sink 304, and can seal to the camera PCB 420 by an O-ring positioned between the camera PCB 420 and the rear chamber cover assembly 410. Thus, in some embodiments, the bottom cover 410 can comprise the heat sink 304 and/or the heat sink 304 can comprise the bottom cover 410.

In some embodiments, the rear chamber cover assembly 410 can enclose the thermoelectric cooler (“TEC”) 424 and/or the thermal conductor 426. Thus, in some embodiments, the TEC 424 can be enclosed within the sealed volume defined by one or more of the top cover 408 and the bottom cover 410. The TEC 424 can, in some embodiments, be thermally coupled by a conductive pathway, also referred to herein as a thermal conductive pathway or as a thermal pathway, to the camera chip 422 and/or to the heat sink 304. The TEC 424 can, in some embodiments, comprise a single stage TEC, or can comprise a TEC having 2 or more stages.

The camera PCB 420 can comprise a multilayer PCB that can include a top layer, a bottom layer, and one or more internal layers. In some embodiments, the camera PCB 420 can be communicatively coupled with the camera chip 422.

In some embodiments, the camera chip 422 can be mounted at a location on the camera PCB 420, and specifically can be mounted on a front of the camera PCB 420. The camera chip 422 can comprise an integrated circuit including a camera and components for driving and/or controlling operation of the camera. The camera can comprise an image sensor such as, for example, a CCD (charge coupled device) image sensor, a CMOS (complementary metal oxide semiconductor) image sensor, or the like. The camera chip 422 can, in some embodiments, capture images of an item outside of the sealed volume formed by the top cover 408 and the bottom cover 410 by the transparent window 416.

In some embodiments, the camera assembly 200 can include conductive pathway that can comprise the thermal conductor 426 as depicted in FIG. 4. The thermal conductive pathway can, in some embodiments, comprise a region of the camera PCB 420, and in some embodiments, can be at the location at which the camera chip 422 is mounted on the camera PCB 420. In such an embodiment, the thermal conductive pathway can extend wholly or partially through the camera PCB 420. The thermal pathway can, in some embodiments comprise the thermal conductor 426 or a matrix of thermal vias that extend through the camera PCB 420 from the top side to the bottom side.

In some embodiments, the conductive pathway, and specifically the thermal conductor 426 can be configured to conduct heat from the camera chip 422 to the TEC 424 to facilitate the temperature control, and specifically the cooling of the camera chip 422. The thermal conductor 426 can be thermally coupled to the camera chip 422 by a first compliant thermal pad (Not shown in the figures) and can be thermally coupled to the TEC 424 by a second compliant thermal pad (not shown in the figures). In some embodiments, the camera PCB 420 can comprise an aperture directly behind the camera chip 422 by which aperture the thermal conductor 426 can directly contact the camera chip 422 thereby increasing heat transfer from the camera chip 422 to the thermal conductor 426.

With reference now to FIG. 5, a schematic depiction of an embodiment of a portion of the camera assembly 200 including a conductive pathway 500 is shown. As seen in FIG. 5, the camera PCB 420 comprises a plurality of layers including a top layer 502, a bottom layer 504, and one or more internal layers 506. As further seen, the camera chip 422 is positioned on a top surface of the camera PCB 420, and the TEC 424 is positioned on a bottom surface of the camera PCB 420. Additionally, one or more connectors are positioned on the camera PCB 420. With specific reference to FIG. 5, each of a camera connector 508 and a TEC connector 510 are positioned on an external surface of the TEC.

As further seen in FIG. 5, the camera connector 508 is electrically and/or communicatively coupled to the camera chip 422 by a copper camera PCB trace(s) 512, and the TEC connector 510 is electrically and/or communicatively coupled to the TEC 424 by the TEC copper PCB Trace(s) 514. In some embodiments, the camera PCB copper conductor trace(s) 512 can comprise a plurality of copper traces including, for example, one or more copper traces for powering the camera chip 422, one or more traces for controlling the camera chip 422, and/or one or more traces for receiving data from the camera chip 422. In some embodiments, the TEC trace 514 can comprise a plurality of copper traces including, for example, one or more traces for powering the TEC 424, one or more traces for controlling the TEC 424, and/or one or more traces for receiving data from the TEC 424.

In some embodiments, one or more of the connectors 508, 510 can be configured to receive power for the associated component(s) enclosed by the chamber covers 408, 410, to receive data from the associated component(s) enclosed by the chamber covers 408, 410, and/or to provide control signals to the component(s) enclosed by the chamber covers 408, 410.

As seen in FIG. 5, each of the camera PCB copper trace 512 and the TEC PCB copper trace 514 extend vertically through one of the top layer 502 or the bottom layer 504, and then horizontally through at least one of the internal layers 506. In some embodiments, each of the camera trace 512 and the TEC trace 514 extends horizontally through at least one of the internal layers 506 while passing under the chamber cover 408, 410, and then each of the camera trace 512 and the TEC trace 514 extends vertically to an external surface of the camera PCB 420. In some embodiments, the camera trace 512 extends vertically through the camera PCB 420 to the top surface of the camera PCB 420 and connects to the camera chip 422, and the TEC trace 514 extends vertically through the camera PCB 420 to the bottom surface of the camera PCB 420 and connects to the TEC 424.

Although FIG. 5 only depicts a camera chip 422 and a TEC 424 components contained within the chamber cover 408, 410 and coupled by a trace 512, 514 to another component such as connectors 508, 510 outside of the chamber covers 408, 410, a person of skill in the art will understand that further components within the chamber cover 408, 410 can similarly be coupled by a trace in at least one internal layer 506 of the camera PCB 420 to one or more components outside of the chamber cover 408, 410.

In some embodiments, all power, data, and/or control connection between components contained within the chamber covers 408, 410 and components outside of the chamber covers 408, 410 is through one or more traces 512, 514 extending through at least one internal layer 506 of the camera PCB 420. Thus, in some embodiments, no wire and/or no wires extend through one or more of the chamber covers 408, 410.

The conductive pathway 500 can comprise a thermally conductive feature configured to facilitate thermal conduction between the camera chip 422 and the TEC 424. The conductive pathway 500 can be a part of the camera PCB 420, or can be separate from the camera PCB 420. In some embodiments, the conductive pathway 500 can extend through an aperture in the camera PCB 430. The conductive pathway 500 can comprise, one or several vias, a thermal conductor, and/or the like.

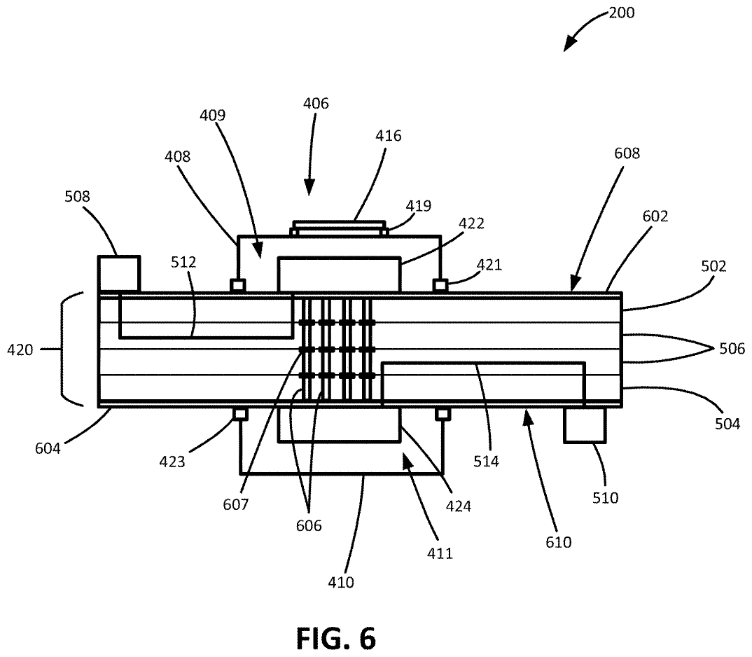

With reference now to FIG. 6, a schematic depiction of an embodiment of a portion of the camera assembly 200 including a plurality of vias is shown. As seen in FIG. 6, the camera PCB 420 comprises a plurality of layers including a top layer 502, a bottom layer 504, and one or more internal layers 506.

The camera PCB 420 further includes one or more plates covering at least a portion of an external surface of the camera PCB 420. These plates can be metal plates, which metal can be, for example, a copper. In some embodiments, the one or more plates can provide a smooth and/or flat surface to facilitate sealing of the area enclosed by the covers 408, 410. Specifically, the one or more plates facilitate sealing engagement between the camera PCB 420 and the O-ring 418.

With reference to FIG. 6, the camera PCB 420 comprises a top layer PCB copper plate 602 and a bottom layer copper plate 604. In some embodiments, the top layer copper plate 602 can comprise a homogenous copper plate, and/or in some embodiments, the bottom layer PCB copper plate 604 can comprise a homogenous copper plate. In some embodiments, one or both of the top copper plate 602 and the bottom copper plate 604 can each be covered by masking. Thus, the top copper plate 602 can be covered by a first masking 608 and the bottom copper plate 604 can be covered by a second masking 610. In some embodiments, the masking can be non-conductive and/or insulative such that the top copper plate 602 and the bottom copper plate 604 are insulated.

In some embodiments, the top copper plate 602 can extend across all or portions of the top of the camera PCB 420 and the bottom copper plate 604 can extend across all or portions of the bottom of the camera PCB 420. In some embodiments, the top copper plate 602 can be smaller than the top of the camera PCB 420 such that an uncovered portion of the camera PCB 420 extends around the top copper plate 602. In some embodiments, the bottom copper plate 604 can be smaller than the bottom of the camera PCB 420 such that an uncovered portion of the camera PCB 420 extends around the bottom copper plate 604.

In some embodiments, the top layer PCB copper plate 602 can extend across at least a portion of the top surface of the camera PCB 420, and the bottom layer PCB copper plate 604 can extend across at least a portion of the bottom surface of the camera PCB 420. In some embodiments, the top layer PCB copper plate 602 can extend at least across portions of the top surface of the camera PCB 420 that couples by the O-ring 418 to the top cover 408, and in some embodiments, the bottom copper plate 604 can extend at least across portions of the bottom surface of the camera PCB 420 that couples by the O-ring 418 to the bottom cover 410.

As further seen, the camera chip 422 is positioned on a top surface of the camera PCB 420, and the TEC 424 is positioned on a bottom surface of the camera PCB 420. In some embodiments, the camera chip 422 is positioned on a top surface of the PCB top side 602 of the camera PCB 420 and the TEC 424 is positioned on a bottom surface of the bottom PCB side 604 of the camera PCB 420. Additionally, one or more connectors are positioned on the camera PCB 420, and specifically are positioned on one or more external surfaces of the camera PCB. With specific reference to FIG. 6, the camera connector 508 is positioned on a top surface of the camera PCB 420 and specifically on a top of the PCB top side 602, and the TEC connector 510 is positioned on a bottom surface of the camera PCB 420 and specifically on the bottom of the bottom plate 604.

As further seen in FIG. 6, the camera connector 508 is electrically and/or communicatively coupled to the camera chip 422 by a camera trace 512, and the TEC connector 510 is electrically and/or communicatively coupled to the TEC 424 by the TEC Trace 514. In some embodiments, one or more of the connectors 508, 510 can be configured to receive power for the associated component(s) enclosed by the chamber covers 408, 410, to receive data from the associated component(s) enclosed by the chamber covers 408, 410, and/or to provide control signals to the component(s) enclosed by the chamber covers 408, 410.

As seen in FIG. 6, each of the camera trace 512 and the TEC trace 514 extend vertically through one of the top copper plate 602 and the top layer 502 or the bottom copper plate 604 and the bottom layer 504, and then horizontally through at least one of the internal layers 506. In some embodiments, each of the camera trace 512 and the TEC trace 514 extends horizontally through at least one of the internal layers 506 while passing under the chamber cover 408, 410, and then each of the camera trace 512 and the TEC trace 514 extends vertically to an external surface of the camera PCB 420. In some embodiments, the camera trace 512 extends vertically through the camera PCB 420 to the top surface of the camera PCB 420 and connects to the camera chip 422, and the TEC trace 514 extends vertically through the camera PCB 420 to the bottom surface of the camera PCB 420 and connects to the TEC 424.

Although FIG. 6 only depicts a camera chip 422 and a TEC 424 contained within the chamber cover 408, 410 and coupled by a trace 512, 514 to another component such as connectors 508, 510 outside of the chamber covers 408, 410, a person of skill in the art will understand that further components within the chamber cover 408, 410 can similarly be coupled by a trace in at least one internal layer 506 of the camera PCB 420 to one or more components outside of the chamber cover 408, 410.

FIG. 6 further depicts thermal coupling of the TEC 424 to the camera chip 422 by a matrix of copper thermal vias 606. In some embodiments, the matrix of thermal vias 606 can be thermally conductive and configured to facilitate thermal connection between the camera chip 422 and the TEC 424. Each of the vias 606 can comprise an aperture extending through at least a portion of the camera PCB 420. In some embodiments, each of the vias 606 can comprise an aperture extending through some or all of the camera PCB 420 and more specifically extending through some or all of the layers 502, 504, 506 of the camera PCB 420. In some embodiments, some or all of the vias 606 can physically connect to one or both of the top plate 602 and the bottom plate 604.

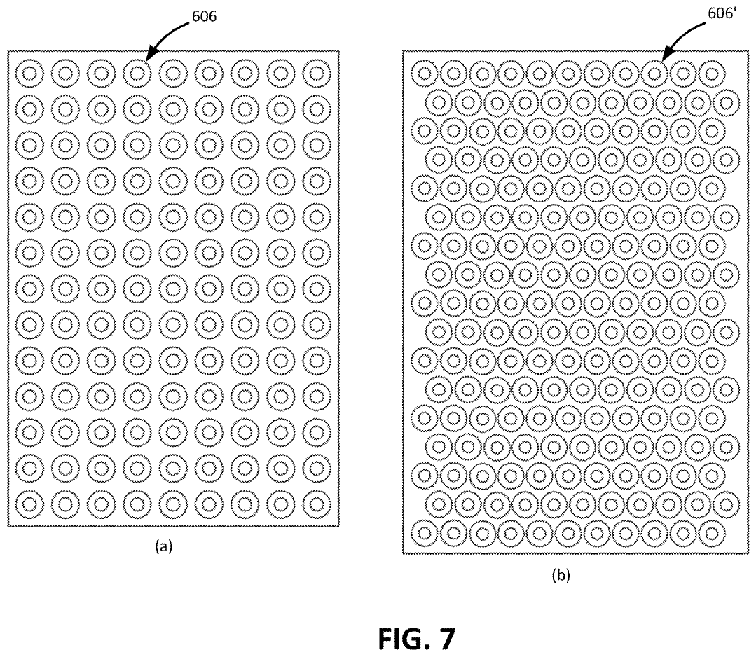

In some embodiments, the copper thermal vias 606 can be arranged within a pattern or matrix. In some embodiments, for example, the vias can be arranged in a grid pattern. In some embodiments, the vias can be arranged in an offset grid pattern. FIG. 7 (a) depicts a plurality of vias 606, each represented by a circle, arranged in a grid pattern without offset. FIG. 7 (b) depicts a plurality of vias 606′, each represented by a circle, arranged in a grid pattern with offset. For example alternate rows vias are offset from adjacent row of vias. The vias 606′ arranged in the offset grid pattern increases via density and enhances thermal transfer compared to the vias 606 arranged in a regular grid.

In some embodiments, the aperture forming each of the vias 606 can be metal lined, metal plated, and/or metal filled. In some embodiments, this metal can be copper, and thus each of the vias 606 can be copper lined, copper plated, and/or copper filled.

In some embodiments, each of the vias 606 can comprise one or more via disks 607. In some embodiments, each of the via disks 607 can comprise a copper disk. The via disk 607 can be coupled to one of the vias 606 such that the via 606 and the via disk 607 are a single unitary piece. In some embodiments, the via disks 607 can be positioned along the via 606 such that they are located between layers in the camera PCB 420.

A collection of exemplary embodiments, including at least some explicitly enumerated as “Examples” providing additional description of a variety of example types in accordance with the concepts described herein are provided below. These examples are not meant to be mutually exclusive, exhaustive, or restrictive; and the present disclosure is not limited to these example examples but rather encompasses all possible modifications and variations within the scope of the issued claims and their equivalents.

Example 1. A camera for capturing images, the camera comprising: a camera chip; a multilayer printed circuit board (“PCB”) communicatively coupled with the camera chip, the PCB comprising a top layer, a bottom layer, and at least one internal layer, wherein traces for powering the camera chip and traces for receiving data from the camera chip extend through the at least one internal layer of the PCB; a chamber cover sealingly coupled to the PCB around the camera chip to define a hermetically sealed volume containing the camera chip.

Example 2. The camera of claim 1, wherein no wire extends through the chamber cover.

Example 3. The camera of any of the preceding or subsequent examples or combination of examples, wherein the chamber cover comprises a top cover sealingly coupled to a top surface of the PCB and a bottom cover sealingly coupled to a bottom surface of the PCB.

Example 4. The camera of any of the preceding or subsequent examples or combination of examples, wherein the top cover is sealingly coupled to the top surface of the PCB by a first gasket located on the top surface of the PCB and extending around the camera chip, and wherein the bottom cover is sealingly coupled to the bottom surface of the PCB by a second gasket located on the bottom surface of the PCB and extending around the camera chip.

Example 5. The camera of any of the preceding or subsequent examples or combination of examples, wherein the top cover comprises a transparent window by which the camera chip can capture images of an item outside of the sealed volume.

Example 6. The camera of any of the preceding or subsequent examples or combination of examples, wherein the transparent window comprises a sapphire window.

Example 7. The camera of any of the preceding or subsequent examples or combination of examples, wherein the bottom cover comprises a heat sink.

Example 8. The camera of any of the preceding or subsequent examples or combination of examples, further comprising a thermo-electric cooler (“TEC”) located inside of the sealed volume and thermally coupled by a conductive pathway to the camera chip and to the heat sink.

Example 9. The camera of any of the preceding or subsequent examples or combination of examples, wherein the PCB comprises TEC traces extending through at least one internal layer of the PCB, wherein the TEC traces power the TEC and control the TEC.

Example 10. The camera of any of the preceding or subsequent examples or combination of examples, further comprising a thermal conductor positioned between the TEC and the camera chip and configured to form a portion of the conductive pathway between the TEC and the camera chip.

Example 11. The camera of any of the preceding or subsequent examples or combination of examples, wherein the camera chip is mounted at a location on the PCB.

Example 12. The camera of any of the preceding or subsequent examples or combination of examples, wherein the thermal conductive pathway comprises a region of the PCB, and wherein the thermal conductive pathway is at the location at which the camera chip is mounted on the PCB and extends through the PCB.

Example 13. The camera of any of the preceding or subsequent examples or combination of examples, wherein the thermal conductive pathway comprises a plurality of vias extending through at least a portion of the PCB.

Example 14. The camera of any of the preceding or subsequent examples or combination of examples, wherein the plurality of vias are arranged in a grid pattern.

Example 15. The camera of any of the preceding or subsequent examples or combination of examples, wherein the plurality of vias are arranged in an offset grid pattern.

Example 16. The camera of any of the preceding or subsequent examples or combination of examples, wherein each of the vias is copper plated or copper filled.

Example 17. The camera of any of the preceding or subsequent examples or combination of examples, wherein the top layer of the PCB is at least partially covered by a first homogenous copper plate, and wherein the bottom layer of the PCB is at least partially covered by a second homogenous copper plate.

Example 18. The camera of any of the preceding or subsequent examples or combination of examples, wherein the first copper plate is covered by a first masking, and wherein the second copper plate is covered by a second masking.

Example 19. The camera of any of the preceding or subsequent examples or combination of examples, wherein the traces extend through the at least one internal layer from a location inside of the hermetically sealed volume to a location outside of the hermetically sealed volume.

Example 20. An imager comprising: a sample receiving area configured to receive a biological sample for imaging; and a camera. The camera comprising: a camera chip; a multilayer printed circuit board (“PCB”) comprising a top layer, a bottom layer, at least one internal layer, and traces extending through the at least one internal layer of the PCB, the traces comprising at least one camera trace for powering the camera chip; and a chamber cover sealingly coupled to the PCB around the camera chip to define a hermetically sealed volume containing the camera chip.

Example 21. The method of any of the preceding or subsequent examples or combination of examples, wherein no wire extends through the chamber cover.

Example 22. The imager of any of the preceding or subsequent examples or combination of examples, wherein the chamber cover comprises a top cover sealingly coupled to a top surface of the PCB and a bottom cover sealingly coupled to a bottom surface of the PCB.

Example 23. The imager of any of the preceding or subsequent examples or combination of examples, wherein the top cover is sealingly coupled to the top surface of the PCB by a first gasket located on the top surface of the PCB and extending around the camera chip, and wherein the bottom cover is sealingly coupled to the bottom surface of the PCB by a second gasket located on the bottom surface of the PCB and extending around the camera chip.

Example 24. The imager of any of the preceding or subsequent examples or combination of examples, wherein the top cover comprises a transparent window by which the camera chip can capture images of an item outside of the sealed volume.

Example 25. The imager of any of the preceding or subsequent examples or combination of examples, wherein the transparent window comprises a sapphire window.

Example 26. The imager of any of the preceding or subsequent examples or combination of examples, wherein the bottom cover comprises a heat sink.

Example 27. The imager of any of the preceding or subsequent examples or combination of examples, further comprising a thermo-electric cooler (“TEC”) located inside of the sealed volume and thermally coupled by a conductive pathway to the camera chip and to the heat sink.

Example 28. The imager of any of the preceding or subsequent examples or combination of examples, wherein the PCB comprises TEC traces extending through at least one internal layer of the PCB, wherein the TEC traces power the TEC and control the TEC.

Example 29. The imager of any of the preceding or subsequent examples or combination of examples, further comprising a thermal conductor positioned between the TEC and the camera chip and configured to form a portion of the conductive pathway between the TEC and the camera chip.

Example 30. The imager of any of the preceding or subsequent examples or combination of examples, wherein the camera chip is mounted at a location on the PCB.

Example 31. The imager of any of the preceding or subsequent examples or combination of examples, wherein the thermal conductive pathway comprises a region of the PCB, and wherein the thermal conductive pathway is at the location at which the camera chip is mounted on the PCB and extends through the PCB.

Example 32. The imager of any of the preceding or subsequent examples or combination of examples, wherein the thermal conductive pathway comprises a plurality of vias extending through at least a portion of the PCB.

Example 33. The imager of any of the preceding or subsequent examples or combination of examples, wherein the plurality of vias are arranged in a grid pattern.

Example 34. The imager of any of the preceding or subsequent examples or combination of examples, wherein the plurality of vias are arranged in an offset grid pattern.

Example 35. The imager of any of the preceding or subsequent examples or combination of examples, wherein each of the vias is copper plated or copper filled.

Example 36. The imager of any of the preceding or subsequent examples or combination of examples, wherein the top layer of the PCB is at least partially covered by a first homogenous copper plate, and wherein the bottom layer of the PCB is at least partially covered by a second homogenous copper plate.

Example 37. The imager of any of the preceding or subsequent examples or combination of examples, wherein the first copper plate is covered by a first masking, and wherein the second copper plate is covered by a second masking.

Example 38. The imager of any of the preceding or subsequent examples or combination of examples, wherein the traces extend through the at least one internal layer from a location inside of the hermetically sealed volume to a location outside of the hermetically sealed volume.

Example 39. A method of imaging a biological sample. The method comprising: receiving a sample within a sample receiving area of an imager; and capturing an image of the sample with a camera. The camera comprising: a camera chip; a multilayer printed circuit board (“PCB”) comprising a top layer, a bottom layer, at least one internal layer, and traces extending through the at least one internal layer of the PCB, the traces comprising at least one camera trace for powering the camera chip; and a chamber cover sealingly coupled to the PCB around the camera chip to define a hermetically sealed volume containing the camera chip.

Example 40. The method of any of the preceding or subsequent examples or combination of examples, wherein no wire extends through the chamber cover.

Example 41. The method of any of the preceding or subsequent examples or combination of examples, wherein the chamber cover comprises a top cover sealingly coupled to a top surface of the PCB and a bottom cover sealingly coupled to a bottom surface of the PCB.

Example 42. The method of any of the preceding or subsequent examples or combination of examples, wherein the top cover is sealingly coupled to the top surface of the PCB by a first gasket located on the top surface of the PCB and extending around the camera chip, and wherein the bottom cover is sealingly coupled to the bottom surface of the PCB by a second gasket located on the bottom surface of the PCB and extending around the camera chip.

Example 43. The method of any of the preceding or subsequent examples or combination of examples, wherein the top cover comprises a transparent window by which the camera chip can capture images of an item outside of the sealed volume.

Example 44. The method of any of the preceding or subsequent examples or combination of examples, wherein the transparent window comprises a sapphire window.

Example 45. The method of any of the preceding or subsequent examples or combination of examples, wherein the bottom cover comprises a heat sink.

Example 46. The method of any of the preceding or subsequent examples or combination of examples, wherein the camera further comprising a thermo-electric cooler (“TEC”) located inside of the sealed volume and thermally coupled by a conductive pathway to the camera chip and to the heat sink.

Example 47. The method of any of the preceding or subsequent examples or combination of examples, wherein the PCB comprises TEC traces extending through at least one internal layer of the PCB, wherein the TEC traces power the TEC and control the TEC.

Example 48. The method of any of the preceding or subsequent examples or combination of examples, wherein the camera further comprising a thermal conductor positioned between the TEC and the camera chip and configured to form a portion of the conductive pathway between the TEC and the camera chip.

Example 49. The method of any of the preceding or subsequent examples or combination of examples, wherein the camera chip is mounted at a location on the PCB.

Example 50. The method of any of the preceding or subsequent examples or combination of examples, wherein the thermal conductive pathway comprises a region of the PCB, and wherein the thermal conductive pathway is at the location at which the camera chip is mounted on the PCB and extends through the PCB.

Example 51. The method of any of the preceding or subsequent examples or combination of examples, wherein the thermal conductive pathway comprises a plurality of vias extending through at least a portion of the PCB.

Example 52. The method of any of the preceding or subsequent examples or combination of examples, wherein the plurality of vias are arranged in a grid pattern.

Example 53. The method of any of the preceding or subsequent examples or combination of examples, wherein the plurality of vias are arranged in an offset grid pattern.

Example 54. The method of any of the preceding or subsequent examples or combination of examples, wherein each of the vias is copper plated or copper filled.

Example 55. The method of any of the preceding or subsequent examples or combination of examples, wherein the top layer of the PCB is at least partially covered by a first homogenous copper plate, and wherein the bottom layer of the PCB is at least partially covered by a second homogenous copper plate.

Example 56. The method of any of the preceding or subsequent examples or combination of examples, wherein the first copper plate is covered by a first masking, and wherein the second copper plate is covered by a second masking.

Example 57. The method of any of the preceding or subsequent examples or combination of examples, wherein the traces extend through the at least one internal layer from a location inside of the hermetically sealed volume to a location outside of the hermetically sealed volume.

This description should not be interpreted as implying any particular order or arrangement among or between various steps or elements except when the order of individual steps or arrangement of elements is explicitly described. Different arrangements of the components depicted in the drawings or described above, as well as components and steps not shown or described are possible. Similarly, some features and sub-combinations are useful and may be employed without reference to other features and sub-combinations. Embodiments of the invention have been described for illustrative and not restrictive purposes, and alternative embodiments will become apparent to readers of this patent. Accordingly, the present invention is not limited to the embodiments described above or depicted in the drawings, and various embodiments and modifications may be made without departing from the scope of the claims below.

What is claimed is:

1. A camera for capturing images, the camera comprising:
a camera chip;
a multilayer printed circuit board (“PCB”) communicatively coupled with the camera chip, the PCB comprising a top layer, a bottom layer, and at least one internal layer, wherein traces for powering the camera chip and traces for receiving data from the camera chip extend through the at least one internal layer of the PCB;
a chamber cover sealingly coupled to the PCB around the camera chip to define a hermetically sealed volume containing the camera chip.

2. The camera of claim 1, wherein no wire extends through the chamber cover.

3. The camera of claim 1, wherein the chamber cover comprises a top cover sealingly coupled to a top surface of the PCB and a bottom cover sealingly coupled to a bottom surface of the PCB.

4. The camera of claim 3, wherein the top cover is sealingly coupled to the top surface of the PCB by a first gasket located on the top surface of the PCB and extending around the camera chip, and wherein the bottom cover is sealingly coupled to the bottom surface of the PCB by a second gasket located on the bottom surface of the PCB and extending around the camera chip.

5. The camera of claim 3, wherein the top cover comprises a transparent window by which the camera chip can capture images of an item outside of the sealed volume.

6. The camera of claim 3, wherein the bottom cover comprises a heat sink.

7. The camera of claim 6, further comprising a thermo-electric cooler (“TEC”) located inside of the sealed volume and thermally coupled by a conductive pathway to the camera chip and to the heat sink.

8. The camera of claim 7, wherein the PCB comprises TEC traces extending through at least one internal layer of the PCB, wherein the TEC traces power the TEC and control the TEC.

9. The camera of claim 8, further comprising a thermal conductor positioned between the TEC and the camera chip and configured to form a portion of the conductive pathway between the TEC and the camera chip.

10. The camera of claim 9, wherein the thermal conductive pathway comprises a region of the PCB, and wherein the thermal conductive pathway is at the location at which the camera chip is mounted on the PCB and extends through the PCB.

11. The camera of claim 10, wherein the thermal conductive pathway comprises a plurality of vias extending through at least a portion of the PCB.

12. The camera of claim 11, wherein the plurality of vias are arranged in a grid pattern, in an offset grid pattern, or a combination thereof.

13. The camera of claim 11, wherein each of the vias is copper plated or copper filled.

14. The camera of claim 1, wherein the top layer of the PCB is at least partially covered by a first homogenous copper plate, and wherein the bottom layer of the PCB is at least partially covered by a second homogenous copper plate.

15. The camera of claim 14, wherein the first copper plate is covered by a first masking, and wherein the second copper plate is covered by a second masking.

16. The camera of claim 1, wherein the traces extend through the at least one internal layer from a location inside of the hermetically sealed volume to a location outside of the hermetically sealed volume.

17. An imager comprising:
a sample receiving area configured to receive a biological sample for imaging; and
a camera comprising:
a camera chip;
a multilayer printed circuit board (“PCB”) comprising a top layer, a bottom layer, at least one internal layer, and traces extending through the at least one internal layer of the PCB, the traces comprising at least one camera trace for powering the camera chip; and
a chamber cover sealingly coupled to the PCB around the camera chip to define a hermetically sealed volume containing the camera chip.

18. The imager of claim 17 wherein no wire extends through the chamber cover.

19. A method of imaging a biological sample, the method comprising:
receiving a sample within a sample receiving area of an imager; and
capturing an image of the sample with a camera, the camera comprising:
a camera chip;
a multilayer printed circuit board (“PCB”) comprising a top layer, a bottom layer, at least one internal layer, and traces extending through the at least one internal layer of the PCB, the traces comprising at least one camera trace for powering the camera chip; and
a chamber cover sealingly coupled to the PCB around the camera chip to define a hermetically sealed volume containing the camera chip.

20. The method of claim 19, the camera further comprises a thermal conductive pathway comprising a plurality of vias extending through the printed circuit board, the plurality of vias being arranged in an offset grid pattern.
